(19) United States
(12) Patent Application Publication
(10) Pub. No.: US 2026/0047167 A1
(43) Pub. Date: Feb. 12, 2026

(54) Semiconductor Device and Method of Seamless Diamond Surface Preparation and Deposition

(71) Applicant: Advent Diamond, Inc., Scottsdale, AZ (US)

(72) Inventors: Jesse Brown, Gilbert, AZ (US); Jose Andres Orozco, Chandler, AZ (US); Anna Zaniewski, Pittsburgh, PA (US); Manpuneet Kaur Benipal, Gilbert, AZ (US)

(73) Assignee: Advent Diamond, Inc., Scottsdale, AZ (US)

(21) Appl. No.: 18/797,052

(22) Filed: Aug. 7, 2024

(51) Int. Cl. H01L 29/16; H01L 21/02; H01L 21/3065; H01L 29/66

(52) U.S. Cl. CPC H10D 62/8303; H01L 21/02376; H01L 21/02527; H01L 21/3065; H10D 48/01

(57) ABSTRACT

A semiconductor device has a substrate with a diamond material. A surface of the substrate is prepared using a first reaction process. The first reaction process can be etching or polishing with oxygen and methane at a gas mixture ratio of about 1:2. The surface of the substrate is exposed to hydrogen plasma prior to the first reaction process. A diamond layer is formed over the surface of the substrate using a second reaction process. The second reaction process can be nucleation or epitaxial growth. The transition from the first reaction process to the second reaction process is seamless. The transition is seamless by nature of the second reaction process continuing from the first reaction process. The diamond layer can be formed over the surface of the substrate using a third reaction process, such as an epitaxial growth. A semiconductor device is formed in the substrate and diamond layer.

### FEDERALLY SPONSORED RESEARCH OR DEVELOPMENT

This invention was made with government support under Award No. 1951263, awarded by National Science Foundation Small Business Innovation Research (SBIR), and Award No. HR00112390101 awarded by Department of Energy Small Business Innovation Research (SBIR). The government has certain rights in the invention.

### FIELD OF THE INVENTION

The present invention relates in general to a semiconductor device and, more particularly, to a semiconductor device and method of seamless diamond surface preparation and deposition.

### BACKGROUND OF THE INVENTION

Semiconductor devices are commonly found in modern electrical products. Semiconductor devices vary in the number and density of electrical components. Discrete semiconductor devices generally contain one type of electrical component, e.g., a light emitting diode (LED), small signal transistor, electrical diode, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, interface circuits, and other signal processing circuits.

Semiconductor devices perform a wide range of functions, such as signal processing, high-speed calculations, transmitting and receiving electromagnetic signals, controlling electrical devices, transforming sunlight to electricity, and creating visual projections for television displays. Semiconductor devices are found in the fields of communications, power conversion, networks, computers, and consumer products. Semiconductor devices are also found in military applications, aerospace, aviation, automotive, data processing centers, industrial controllers, and office equipment.

Diamond material has been used as a substrate for semiconductor devices and provides a number of advantages, such as hardness, thermal conductivity, electron mobility, wide bandgap, radiation hardness, and thermal and chemical stability. A diamond epitaxial layer can be grown over a diamond substrate and semiconductor regions can be formed in the epitaxial layer.

The diamond epitaxial layer should be grown on a smooth substrate surface to reduce defects. Various diamond surface preparation methods, such as polishing, sputtering, and reactive ion etching, can cause sub-surface damage and roughen the surface, which will propagate through the diamond epitaxial layer. Starting and stopping epitaxial growth of doped and intrinsic epitaxial diamond can produce defects at each interface. Defects which propagate from the starting substrates sub-surface damage or interfacial defects during sequential growths are detrimental to the semiconductor device performance. Traditional diamond polishing methods to achieve smooth surfaces involve mechanical processes, whereby abrasive grit is used to remove material from the surface, but due to the brittle nature of diamond, this leads to surface and sub-surface damage. The abrasive grit can also be difficult to remove on an atomic level, which leads to interface defect formation, detrimental to the quality of diamond epitaxial growth.

For other semiconductors, high temperature annealing is used to heal the crystallinity from polishing or etching damage; however, for diamond, very high temperatures (>1300° C.) are required for annealing. Diamond is in a metastable state of carbon at atmospheric pressure, which results in graphitization of diamond occurring at high temperatures. Standard reactive ion etching can be used to reduce surface roughness and/or thin diamond wafers but causes surface and subsurface damage and reduces the crystalline quality of subsequent epitaxial diamond depositions. As an example, surface reactive ion etching can create defect sites for defect propagation into epitaxially deposited layers.

The diamond epitaxial layer is typically grown in stages. The current state of the art and standard practice of diamond deposition employs an abrupt transition from hydrogen plasma into diamond growth. Yet, an abrupt transition can create defects at the interface and those defects can propagate through the grown diamond material. Defect density is higher at interface, thereby increasing the likelihood of introducing interface defects that will propagate into the epitaxial layer or other newly grown layers.

Impurities, defects, and non-uniform step edges create a non-uniform starting surface for diamond epitaxial layers. The non-uniformities can propagate through the bulk where different growth rates around these impurities will produce wildly different final surfaces and are obvious on the final surface. Uniform and consistent final surfaces are required for the realization of diamond as a semiconducting material and the fabrication of high-performance diamond-based devices.

### BRIEF DESCRIPTION OF THE DRAWINGS

FIGS. 1a-1c illustrate a semiconductor wafer with a plurality of semiconductor die;

FIGS. 2a-2c illustrate a process of forming a diamond epitaxial layer over a diamond substrate;

FIGS. 3a-3c illustrate surface preparation, nucleation, and growth of the diamond epitaxial layer;

FIG. 4 is a flowchart of seamless diamond surface preparation and deposition;

FIGS. 5a-5c illustrate etching of the surface of the diamond substrate during seamless diamond step 1; and

FIGS. 6a-6c illustrate a semiconductor device formed within the diamond epitaxial layer and diamond substrate.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Terms such as first, second, etc. may be used herein to describe various elements, although these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

When an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Terms such as “upper,” “lower,” “bottom,” “intermediate,” “middle,” “top,” and the like may be used herein to describe various elements, although these elements should not be limited by these terms. These terms are only used to distinguish one element from another. For example, a first element could be termed an “upper” element and, similarly, a second element could be termed an “upper” element depending on the relative orientations of these elements, without departing from the scope of the present disclosure. Terms such as “over” and “above” refer to one element being within the vertical projection of another element.

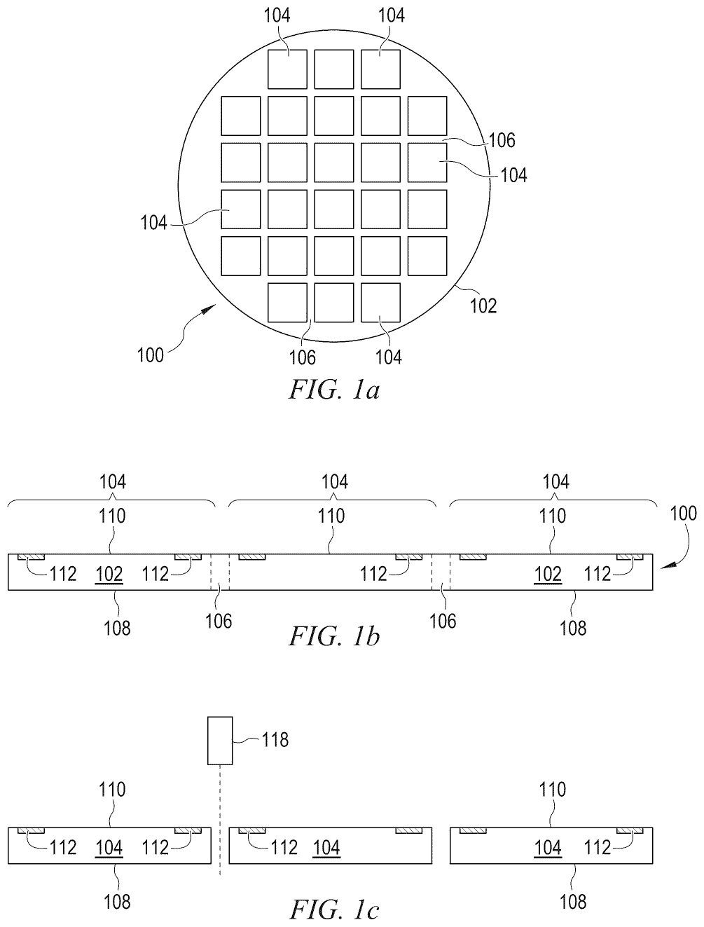

FIG. 1a shows semiconductor wafer or substrate 100 with a base substrate material 102, such as silicon (Si), SiC, cubic silicon carbide (3C-SiC), germanium, aluminum phosphide, aluminum arsenide, gallium arsenide, gallium nitride, indium phosphide, and all families of III-V and II-VI semiconductor materials for structural support. In one embodiment, base substrate material 102 includes synthesized diamond. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 30-100 millimeters (mm) or more.

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, discrete semiconductor devices, or other signal processing circuit.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or unit (KGD/KGU) post singulation.

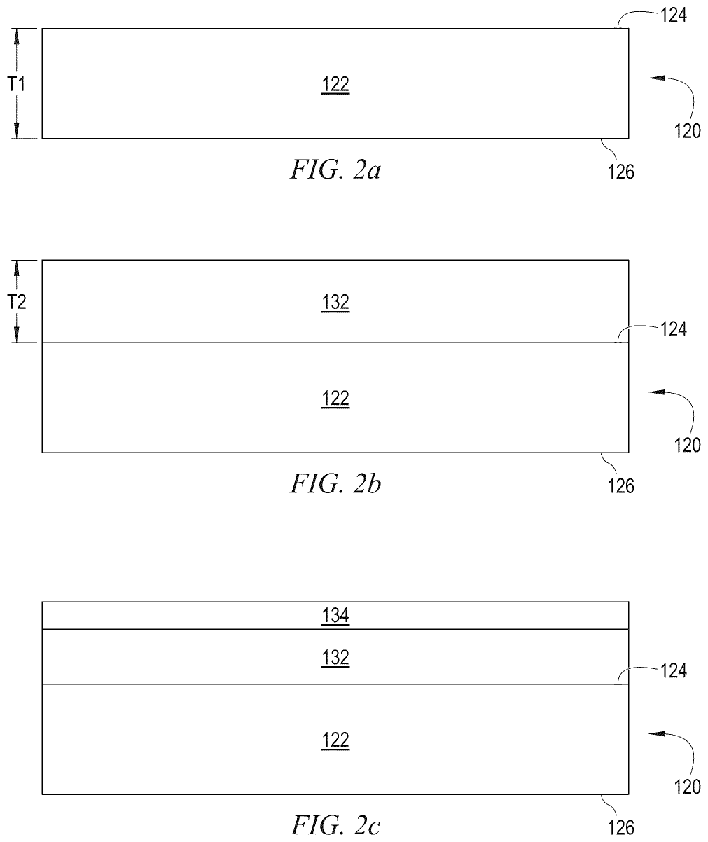

FIG. 2a shows further detail of substrate 120 as the afore-mentioned diamond variant of substrate 100. Substrate 120 has a major surface 124 and major surface 126, opposite major surface 124. Substrate 120 can be a synthesized diamond material 122 formed from crystallized carbon under high temperature and/or high pressure. In particular, diamond material 122 can be synthesized by chemical vapor deposition (CVD), plasma-enhanced chemical vapor deposition (PECVD), or high-pressure, high temperature diamond (HPHT), yet exhibit the same chemical and physical properties as naturally-occurring diamond. For example, CVD creates a carbon plasma or other hydrocarbon gas mixture over a non-diamond substrate onto which the carbon atoms deposit to form diamond material. In CVD, varying amounts of gases are introduced into a reaction chamber and energized over the non-diamond substrate. The non-diamond substrate is selected for its compatibility to grow diamond and its crystallographic orientation. In one embodiment, the non-diamond substrate can be sapphire, or iridium, or a combination thereof both. The gases are carbon (typically methane) and hydrogen with a typical gas mixture ratio of 1:99. Hydrogen selectively etches off non-diamond carbon. The gases are ionized into chemically active radicals in the growth chamber using microwave, hot filament, arc discharge, welding torch, laser, or electron beam. CVD provides the ability to grow diamond over large areas and on various substrates, and the fine control over the chemical impurities and thus properties of the diamond produced. In its final form, diamond substrate 120 has a thickness T1 in the range of 10.0 μm to 10.0 cm, or preferably in the range of 50.0 μm to 500.0 μm.

Semiconductor substrate 120 with synthesized diamond material 122 exhibits useful properties of hardness (10 Mohs or less), thermal conductivity (10-2000 W/m²K), electron mobility, wide bandgap (5.5 eV), radiation hardness, and thermal and chemical stability. Diamond is an electrical insulator and thermal conductor. Diamond can become an electrical conductor by implanting impurities, such as boron (p-type) or phosphorus (n-type). Such impurities contain one more or one fewer valence electrons than carbon and will turn synthetic diamond into p-type or n-type semiconductor material. As such, substrate 120 is applicable to semiconductor devices, such as power transistors, diodes, high frequency transistors, light emitting diodes (LED), ultra-violet (UV) light detectors, quantum sensing, quantum computing, high-power semiconductor devices, radiation detection, and other high energy semiconductor devices.

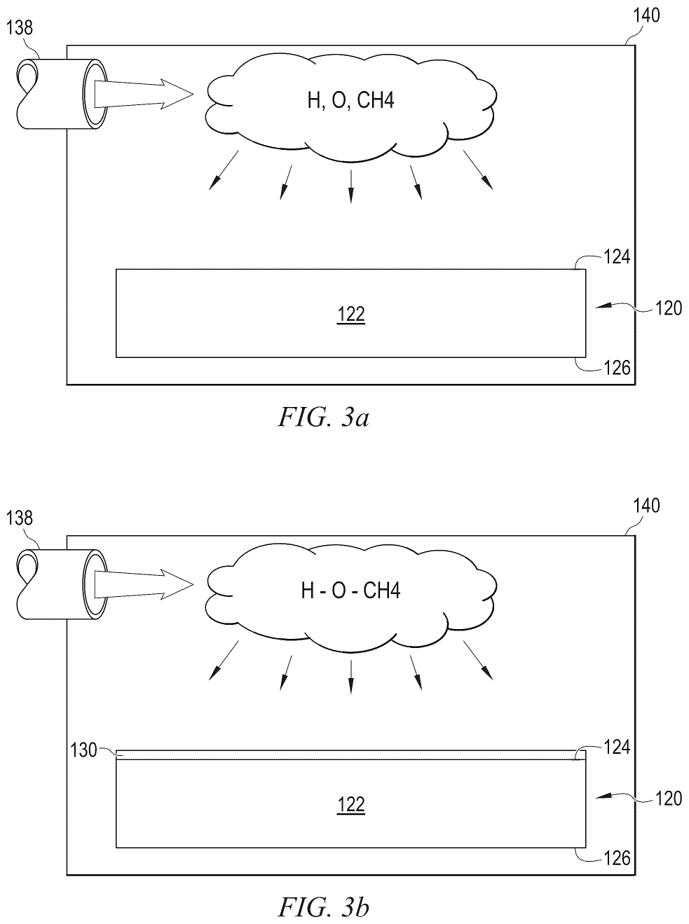

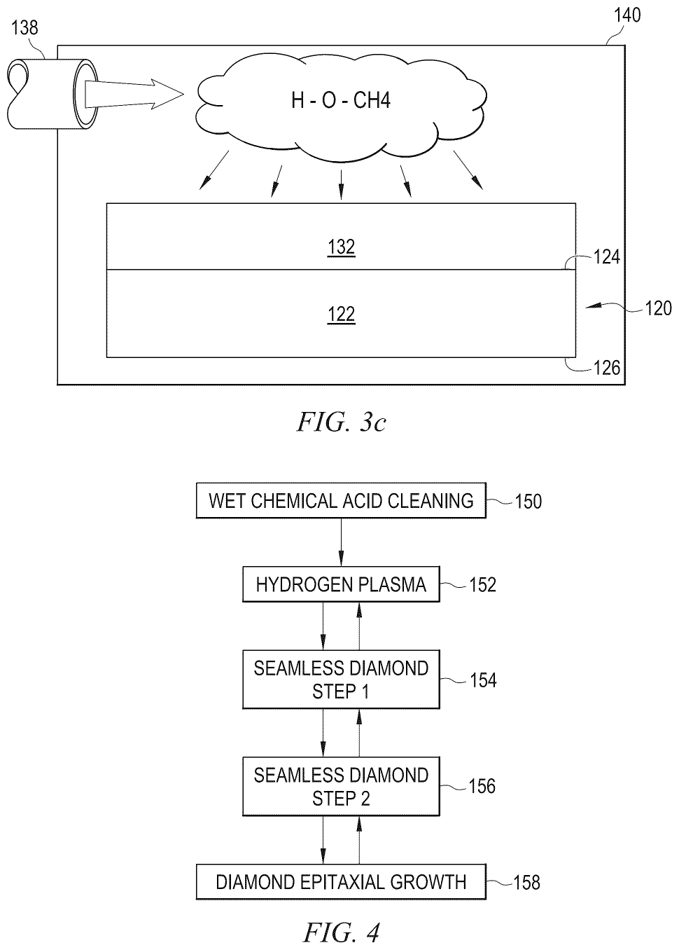

In preparation for formation of a semiconductor device on substrate 120, surface 124 is prepared, repurposed, or otherwise healed for epitaxial growth or other deposition of the next diamond layer. In FIG. 3a, hydrogen (H), oxygen (O), and carbon (C) gas are introduced through conduit 138 into reaction chamber 140 during PECVD on a CVD or HPHT diamond substrate 120 for in-situ plasma treatment. Methane (CH4) can be used to contribute H and C. The plasma treatment serves to prepare surface 124 for the interface between two diamond materials (i.e., diamond material 122 and to-be-grown diamond layer 130/132) based on a mechanism of seamless and sequential etching and growth of diamond to minimize starting surface roughness, interface impurities, and defect propagation into subsequently deposited epitaxial diamond layers.

FIG. 4 is a flowchart of a seamless diamond surface preparation and growth process applied to surface 124 of substrate 120. In step 150, surface 124 undergoes wet chemical acid cleaning. In step 152, a hydrogen plasma is introduced into reaction chamber 140. In general, the hydrogen plasma is introduced into reaction chamber 140 for up to 100 minutes with H2 flow of 10-1000 standard cubic centimeters per minute (sccm), pressure of 10.0-200.0 torr, substrate temperature of 600-1100° C., and microwave power of 0.1-10.0 kW.

In step 154, seamless diamond step 1 is a first reaction process and uses a chemistry to favor etching. Seamless diamond step 1 is a first reaction process by nature of substrate 120 being disposed in reaction chamber 140 and being subjected to H—O—C chemistry. In general, the H—O—C plasma is introduced into reaction chamber 140 during seamless diamond step 1 for up to 500 minutes with H2 flow of 100-1000 sccm, O2 flow of 0.001-25.0 sccm, CH4 flow of 0.002-49.0 sccm, pressure of 30.0-300.0 torr, substrate temperature of 900-1300° C., and microwave power of 0.1-10.0 kW. In seamless diamond step 1, a portion of surface 124 is removed by the first reaction process, e.g., etching and/or plasma polishing. Plasma polishing involves chemical etching via ignition of a plasma source and the chemical reactions thereof to etch the surface to a smooth state. The effect of plasma etching can be achieved by cycling between seamless diamond step 1 and seamless diamond step 2, resulting in reduction in thickness of the substrate or growth, depending on the emphasis.

Polishing and other plasma-based processes, such as reactive ion etching (RIE) or inductively coupled plasma (ICP) etching, for smoothing the diamond surface can produce graphitization or amorphous carbon on the surface and may create subsurface damage. Graphitization and amorphous carbon on the diamond surface can be removed using a wet chemical etching process such as piranha clean or a sulfuric/nitric clean.

A proper gas mixture ratio of oxygen to methane is important for the etching and surface preparation. In one embodiment, a gas mixture ratio of 1:2 (one part oxygen to two parts methane) etches surface 124, particularly at high temperatures in the range of 900-1300° C. In other embodiments, the gas mixture ratio of oxygen to methane can be in the relative range from 1:1 to 1:3, or preferably from 1.1:1.9 to 0.9:2.1. A proper gas mixture ratio of oxygen to methane reduces or prevents formation of hillocks.

The etch rate being higher than nucleation or deposition rate tends to smoothen and planarize surface 124 as part of the surface preparation. While hydrogen plasma is a chemical etch mechanism known to preferentially etch sp² bonded graphitized carbon, or amorphous carbon, and terminate the diamond surface with atomic hydrogen, the addition of oxygen to the hydrogen plasma preferentially etches threading dislocations. The addition of methane prevents the exaggeration of these threading dislocations etch pits, thus smoothing the surface.

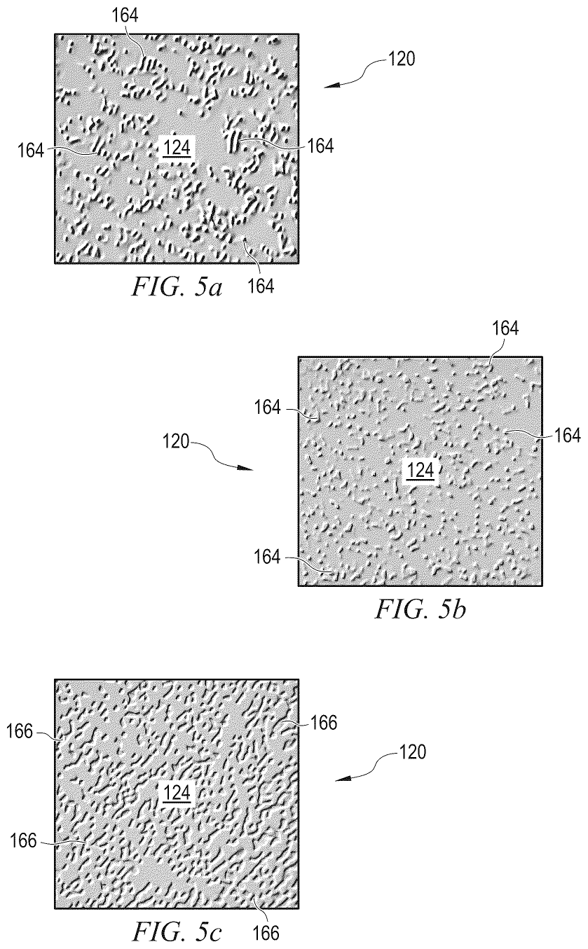

Seamless diamond step 1 reduces total defects, as well as defect density, in surface 124 in preparation for diamond layer 130. FIG. 5a-5c show a top view of surface 124 at various times during seamless diamond step 1. In FIG. 5a, surface 124 has peaks 144 at the start of seamless diamond step 1. Peaks 144 may be 20-50 nanometers (nm) in height. In FIG. 5b, after one hour of seamless diamond step 1, peaks 144 are reduced by the etching process, say down to 5-10 nm. In another embodiment, 60 nm of surface 124 can be etched in three hours to improve surface roughness by a factor of two. In FIG. 5c, after three hours of seamless diamond step 1, peaks 144 are substantially eliminated by the etching process. In fact, peaks 144 from FIGS. 5a-5b may become depressions or pits 146 in FIG. Sc. Seamless diamond step 1 reduces roughness by reducing peaks 144 or creating depressions 146, thereby healing surface 124. The smooth surface 124 provides an abrupt doping interface and reduces defect densities at/across the interface of two diamond materials for better device performance.

In step 156, seamless diamond step 2 is a second reaction process and uses a chemistry to favor nucleation. Seamless diamond step 2 is a second reaction process by nature of substrate 120 being disposed in reaction chamber 140 and being subjected to H—O—C chemistry. In general, H—O—C plasma is introduced into reaction chamber 140 during seamless diamond step 2 for up to 500 minutes with H2 flow of 100-1000 sccm, O2 flow of 0.001-25.0 sccm, CH4 flow of 0.002-49.0 sccm, pressure of 10.0-280.0 torr, substrate temperature of 700-1000° C., and microwave power of 0.1-10.0 kW. Accordingly, as shown in FIG. 3b, diamond epitaxial layer 130 is grown on surface 124 by the second reaction process, i.e., nucleation or epitaxial growth.

Again, a proper gas mixture ratio of oxygen to methane is important for nucleation. In one embodiment, a gas mixture ratio of 1:2 (one part oxygen to two parts methane) etches surface 124, particularly at high temperatures in the range of 900-1300° C. In other embodiments, the gas mixture ratio of oxygen to methane can be in the relative range from 1:1 to 1:3, or preferably from 1.1:1.9 to 0.9:2.1.

In step 158, diamond homoepitaxial growth is performed over surface 124. Diamond homoepitaxial growth is a third reaction process by nature of substrate 120 being disposed in reaction chamber 140 and being subjected to H—O—C chemistry. In general, the H—O—C plasma is introduced into reaction chamber 140 during diamond homoepitaxial growth for up to 10's of μm per hour with H2 flow of 100-1000 sccm, O2 flow of 0.0-24.0 sccm, CH4 flow of 0.003-50.0 sccm, pressure of 10.0-280.0 torr, substrate temperature of 700-1300° C., and microwave power of 0.1-10.0 kW. Accordingly, diamond epitaxial layer 132 is grown over surface 124, as shown in FIG. 3c. Diamond epitaxial layer 130 is shown as being integrated into diamond epitaxial layer 132.

In a first specific example, in hydrogen plasma step 152, the hydrogen plasma is introduced into reaction chamber 140 for 10-60 minutes with H2 flow of 400-600 sccm, pressure of 30.0-70.0 torr, substrate temperature of 700-1000° C., and microwave power of 0.5-3.0 kW. In seamless diamond step 1, the H—O—C plasma is introduced into reaction chamber 140 for 5-200 minutes with H2 flow of 400-600 sccm, O2 flow of 0.25-3.0 sccm, CH4 flow of 0.5-6.0 sccm, pressure of 50.0-90.0 torr, substrate temperature of 1000-1150° C., and microwave power of 0.5-3.0 kW. In seamless diamond step 2, the H—O—C plasma is introduced into reaction chamber 140 for 1-100 minutes with H2 flow of 400-600 sccm, O2 flow of 0.25-3.0 sccm, CH4 flow of 0.5-6.0 sccm, pressure of 30.0-60.0 torr, substrate temperature of 700-900° C., and microwave power of 0.5-3.0 kW. In diamond epitaxial growth step 158, the H—O—C plasma is introduced into reaction chamber 140 up to 200 minutes with H2 flow of 400-600 sccm, O2 flow of 0.001-2.9 sccm, CH4 flow of 0.51-7.0 sccm, pressure of 30.0-60.0 torr, substrate temperature of 800-1000° C., and microwave power of 0.5-3.0 kW.

In a second specific example, in hydrogen plasma step 152, the hydrogen plasma is introduced into reaction chamber 140 for 15 minutes with H2 flow of 394 sccm, pressure of 60 torr, substrate temperature of 820° C., and microwave power of 1.0 kW. In seamless diamond step 1, the H—O—C plasma is introduced into reaction chamber 140 for 15 minutes with H2 flow of 394 sccm, O2 flow of 2.0 sccm, CH4 flow of 4.0 sccm, pressure of 70 torr, substrate temperature of 1060° C., and microwave power of 1.2 kW. In seamless diamond step 2, the H—O—C plasma is introduced into reaction chamber 140 for 15 minutes with H2 flow of 394 sccm, O2 flow of 2.0 sccm, CH4 flow of 4.0 sccm, pressure of 55 torr, substrate temperature of 840° C., and microwave power of 1.2 kW.

In particular, notice the change in reaction parameters from seamless diamond step 1 to seamless diamond step 2 involves changing pressure from 70 torr to 55 torr and temperature from 1060° C. to 840° C. Substrate temperature decreases with lower pressure. Changing pressure and/or temperature in reaction chamber 140 can be manual or automatic, i.e., without operator intervention, but nonetheless be considered continuous and seamless, without any delay, wait-time, pausing, stoppage, or other interruption in the overall reaction process, other than the adjustment to the reaction chamber pressure and/or temperature.

When the in-situ healing step and nucleation both are near a critical point of the diamond growth phase space, in-situ healing is very slowly etching, and by changing the reaction chamber pressure and/or temperature the surface chemistry shifts to nucleation which is very slowly growing. By explicitly using plasma chemistry near the etching and growth equilibrium state any interface defects are likely to be removed, preventing the introduction and propagation of interface defects into the epitaxial layer.

In diamond epitaxial growth step 158, the H—O—C plasma is introduced into reaction chamber 140 for up to and including but not limited to 500 minutes with H2 flow of 394 sccm, O2 flow of 0.75 sccm, CH4 flow of 5.25 sccm, pressure of 55 torr, substrate temperature of 850° C., and microwave power of 1.2 kW.

As discussed in the background, any material transition in the reaction process creates an interface between adjacent layers, resulting in defects at the interface, which can propagate through the grown diamond material. In a seamless transition between seamless diamond step 1 and seamless diamond step 2, the process does not stop or even pause. Rather, reaction chamber parameters are adjusted for a continuous and seamless transition between different rates of nucleation. As noted in the above second specific example, all process parameters remained the same except reaction chamber pressure, i.e., changing pressure typically changes temperature. Lower pressure leads to lower temperature. Accordingly, the process continues from, for example, seamless diamond step 1 to seamless diamond step 2 without interruption or delay, or any other pause in the process to change parameters, other than the adjustment to the reaction chamber pressure. The change from seamless diamond step 1 to seamless diamond step 2 is thus considered to be continuous and seamless. Changing reaction chamber pressure changes temperature, along with proper gas mixture, and the process seamlessly shifts from etching to nucleation. Likewise, the same operation continues, for example, from seamless diamond step 2 back to seamless diamond step 1, or from seamless diamond step 2 to diamond homoepitaxial growth, without interruption or delay, or any other pause in the process to change parameters. Changing pressure in reaction chamber 140 changes temperature, along with proper gas mixture, and the process seamlessly shifts from nucleation back to etching or on to epitaxial growth. The etching or nucleation or deposition continues without stoppage that could introduce defects in interface layer(s). The seamless transition from seamless diamond step 1 to seamless diamond step 2 is actually achieved by a combination of minimal parameter changes, i.e., pressure and/or temperature, as well as maintaining proper oxygen to methane gas mixture ratio.

Changing one or more reaction chamber parameters, e.g., pressure and/or temperature, seamlessly shifts from slow etching to nucleation at a slow growth rate. Another key feature/requirement is the change in temperature is around a critical point, referred to as a roughening transition temperature (about 1000° C.). Above the roughening transition temperature, during seamless diamond step 1, surface 124 of substrate 120 is rough or irregular and not reflective. Below the roughening transition temperature, during seamless diamond step 2, surface 124 is planar and reflective.

In another embodiment, the order of the processing steps in FIG. 4 can be changed. For example, step 152 can proceed to step 156 or step 158, and step 154 can proceed to step 158. Step 158 can proceed to step 154 or step 152, and step 156 can proceed to step 152. Step 158 can proceed to step 156, step 156 can proceed to step 154, and step 154 can proceed to step 152. For example, seamless diamond step 2 can cycle back to seamless diamond step 1, then perform seamless diamond step 1 and step 2 again, and cycle back to seamless diamond step 1, repeating as many times as desired. The processing steps can be cycled, as well as the time at each step and the number of times the steps are repeated. Different gas species with substantial chemical equivalency, can be substituted, as an example, substituting oxygen for CO₂, including a dopant gas including but not limited to diborane, nitrogen, phosphine, trimethylborane, and trimethylphoshine.

In another embodiment, the process can continue to diamond homoepitaxial growth in step 158 after seamless diamond step 1.

In another embodiment, the process can stop after seamless diamond step 1 if the goal is to only prepare surface 124 of substrate 120, possibly for later continued processing. For example, one manufacturer can perform seamless diamond step 1 and then transfer to the diamond substrate or wafer with its surface pre-prepared to another manufacturer to perform seamless diamond step 2 or other nucleation or deposition.

Returning to FIG. 2b, diamond layer 132 is grown over surface 124 of substrate 120 using CVD, PEVCD, or HPHT, as described above. In one embodiment, diamond layer 132 is a single crystalline (e.g., (111), (100)), or polycrystalline, intrinsic diamond material, i.e., having no impurities. Diamond layer 132 has a thickness T2 in the range of 10.0 nm to 300.0 μm.

In FIG. 2c, diamond material 132 is doped with an n-type impurities, such as phosphorus, with a concentration in the range of 10¹⁴ cm⁻³ to 10²¹ cm⁻³, or preferably 10¹⁶ cm⁻³ to 10²⁰ cm⁻³ to form an n-type region as diamond layer 134. The n-type diamond layer 134 allows for formation of electrical semiconductor devices over substrate 120, while utilizing the attributes of diamond, including hardness, thermal conductivity, wide bandgap, and useful mechanical properties.

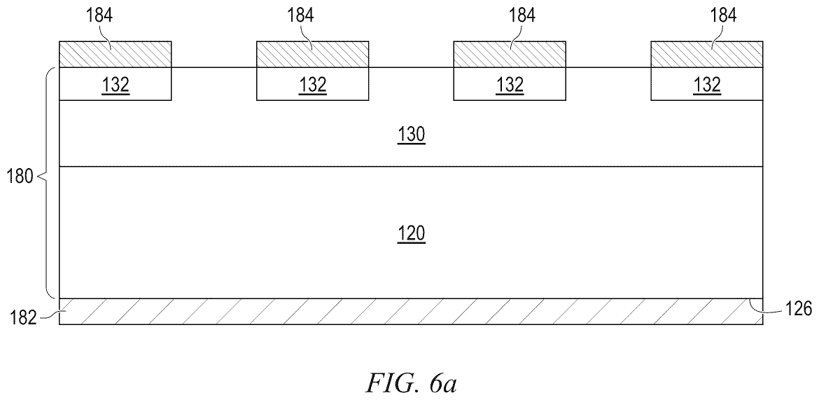

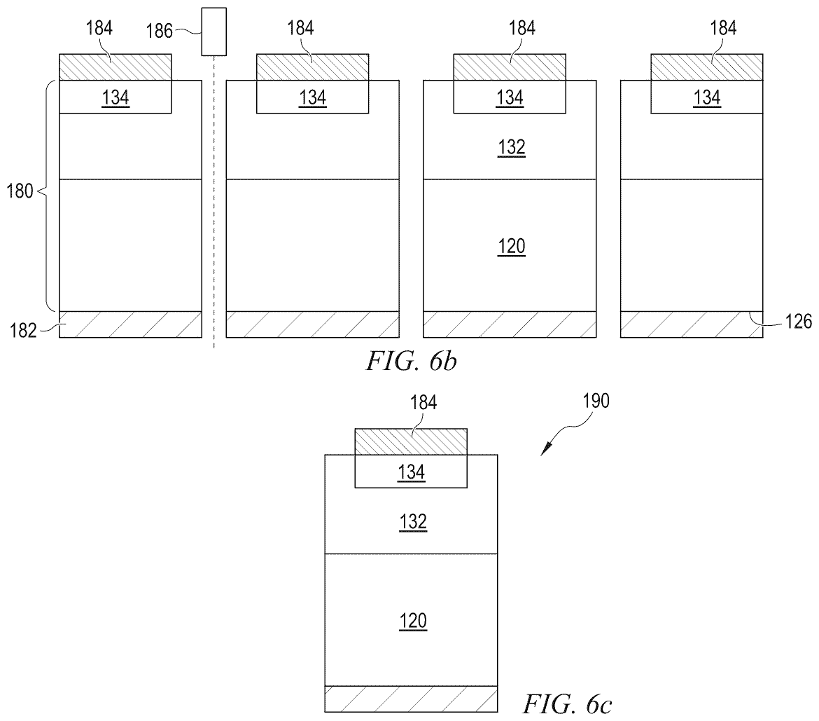

FIG. 6a illustrates an example of forming a diode within substrate 120 and diamond material 132-134. Substrate 120 and diamond material 132 are doped with p-type impurities, such as boron, with a concentration in the range of 5×10¹⁴ cm⁻³ to 5×10¹⁵ cm⁻³. P-type substrate 120 and diamond layer 132 and n-type diamond layer 134 create a P-N junction to function as diode 180.

An electrically conductive layer 182 is formed over surface 126 of substrate 120 and electrically conductive layer 184 is formed over diamond layer 132 using PVD, CVD, electrolytic plating, electroless plating process, or other suitable metal deposition process. Conductive layers 182 and 184 can be one or more layers of Al, Cu, Sn, Ni, Au, Ag, or other suitable electrically conductive material. Conductive layer 182 and 184 operate as contact pads electrically connected to diode 180.

In FIG. 6b, diamond substrate 120 and diamond epitaxial layer 132 are singulated using a saw blade or laser cutting tool 186 into individual semiconductor die 190. FIG. 6c shows one semiconductor die 190 functioning as diamond-based diode 180. Diamond substrate 120 and diamond epitaxial layer 132 can be used to form other semiconductor devices, as described and embodied in semiconductor die 104.

In summary, the two-step seamless diamond process of etching and nucleation is useful to remove surface and sub-surface damage, reduce roughness of diamond materials, enhance sharp doping profile, and improve doping uniformity. The seamless diamond process creates intrinsic diamond material layers, ready for doping to form components/devices crafted from these superior-quality diamond layers for applications in electrification, telecommunications and quantum technologies. Diamond exhibits remarkable electrical and material properties, surpassing those of GaN and SiC, and the seamless diamond process translates these properties into exceptional semiconductor device performance and introduce diamond semiconductor devices with unparalleled specifications and performance to the commercial market, spurring innovation in electrification, telecommunications and quantum applications.

The diamond surface modification steps are also useful for the manufacturing of materials for diamond-based electrical devices, as fabrication steps in device manufacturing, as steps in creating diamond materials for industrial and gemstone applications, and in other applications where diamond materials are created and/or processed. The seamless diamond process can also be used to improve the optical clarity and properties of diamond products in which the optical properties are hindered by interface, surface and subsurface defects including graphitization.

The H—O—C based plasma of two-step seamless diamond process provides an environment which is nearly at equilibrium between etching and growth of diamond and allows for diamond growth while simultaneously etching and/or migration and/or annihilation of dislocations. The two steps of seamless diamond shift the equilibrium from a slow etching in seamless diamond step 1, to a slow growth or nucleation in seamless diamond step 2. The seamless diamond process is beneficial for removing impurities at the starting surface/interface by vaporizing diamond and non-diamond material alike. Additionally, the seamless diamond process creates an environment for smoothing non-uniform surface structure (i.e., steps) and dislocations to enable a seamless transition across the interface. The seamless diamond process is also beneficial for plasma chemistry and enables a seamless transition of plasma chemistry from hydrogen plasma to diamond growth, avoiding the abrupt transition between those two plasma chemistries.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a substrate including a diamond material;
preparing a surface of the substrate using a first reaction process including oxygen and methane at a gas mixture ratio of about 1:2; and
forming a diamond layer over the surface of the substrate using a second reaction process, wherein transition from the first reaction process to the second reaction process is seamless.

2. The method of claim 1, wherein the first reaction process includes etching or plasma polishing.

3. The method of claim 1, wherein the second reaction process includes nucleation or epitaxial growth.

4. The method of claim 1, further including exposing the surface of the substrate to hydrogen plasma prior to the first reaction process.

5. The method of claim 1, further including forming the diamond layer over the surface of the substrate using a third reaction process.

6. The method of claim 5, wherein the third reaction process includes an epitaxial growth.

7. A method of making a semiconductor device, comprising:
providing a substrate;
forming a prepared surface of the substrate by a first reaction process; and
forming a diamond layer over the prepared surface of the substrate using a second reaction process continuing from the first reaction process.

8. The method of claim 7, wherein the first reaction process includes etching or polishing.

9. The method of claim 7, wherein the second reaction process includes nucleation or epitaxial growth.

10. The method of claim 7, wherein the first reaction process includes oxygen and methane at a gas mixture ratio of about 1:2.

11. The method of claim 7, further including forming the diamond layer over the prepared surface of the substrate using a third reaction process.

12. The method of claim 11, wherein the third reaction process includes an epitaxial growth.

13. The method of claim 7, further including forming a semiconductor device in the substrate and diamond layer.

14. A semiconductor device, comprising:
a substrate including a prepared surface by a first reaction process; and
a diamond layer formed over the prepared surface of the substrate by a second reaction process continuing from the first reaction process.

15. The semiconductor device of claim 14, wherein the first reaction process includes etching or polishing.

16. The semiconductor device of claim 14, wherein the second reaction process includes nucleation or epitaxial growth.

17. The semiconductor device of claim 14, wherein the first reaction process includes oxygen and methane at a gas mixture ratio of about 1:2.

18. The semiconductor device of claim 14, wherein the diamond layer includes a doped region.

19. The semiconductor device of claim 14, wherein the diamond layer is formed over the prepared surface of the substrate by a third reaction process.

20. The semiconductor device of claim 14, further including a semiconductor device formed in the substrate and diamond layer.
